(19) United States
(12) Patent Application Publication
(10) Pub. No.: US 2002/0079980 A1
(43) Pub. Date: Jun. 27, 2002

(54) Apparatus comprising a phase and amplitude-modulated signal transmitter, method implemented in such apparatus

(76) Inventor: Jean Alain Chabas, Cesson-Sevigne (FR)

Correspondence Address: U.S. Philips Corporation, 580 White Plains Road, Tarrytown, NY, 10591, US

(21) Appl. No.: 09/989,257

(22) Filed: Nov. 20, 2001

(30) Foreign Application Priority Data
Nov. 21, 2000 (FR) 0015013

(51) Int. Cl. H03C 1/00

(52) U.S. Cl. 332/149

(57) ABSTRACT

This apparatus comprises an amplitude and phase-modulated signal transmitter. This transmitter is formed by a non-linear amplifier (30) for supplying signals based on a portable signal generator (25) to an antenna (10). The apparatus comprises an amplitude modulator (39) which is placed between the amplifier (30) and the antenna (10) and a phase modulator (37) which is placed at the input of the amplifier (30).

The invention relates to an apparatus comprising an amplitude-modulated signal transmitter preferably formed by a non-linear amplifier for supplying signals to a user circuit based on a carrier signal generator.

The invention also relates to a method of phase and amplitude-modulating signals.

The invention finds interesting applications in the field of radio communications, notably those which correspond to the GSM EDGE standards. The use of non-linear amplifiers is essential because of their good energy efficiency.

An apparatus of this type is described in patent document WO-0048309. In this known apparatus one is confronted with problems of distortions generated by the nonlinear amplifier.

The present invention proposes an apparatus of the type mentioned in the opening paragraph which permits to largely remedy the problems of distortions.

For this purpose, such an apparatus is characterized in that it comprises at least an amplitude modulator which has an amplitude modulation input for receiving information to be transmitted and which is placed between said amplifier and said user circuit.

The idea of the invention is that when the amplitude modulator is placed between the amplifier and the user circuit, non-linearities of the amplifier are largely done away with because this amplifier operates with signals that have a constant amplitude.

According to an important characteristic feature of the invention, the apparatus comprises a filter circuit situated between the user circuit and said amplifier, which permits of attenuating any distortions and providing a large spectrum purity of the transmitted signals. It should be observed that this filter, which may be of the low-pass or band-pass type, may be realized in a very simple way by using surface wave filter techniques which are known to a man skilled in the art.

These and other aspects of the invention are apparent from and will be elucidated, by way of non-limitative example, with reference to the embodiment(s) described hereinafter.

In the drawings:

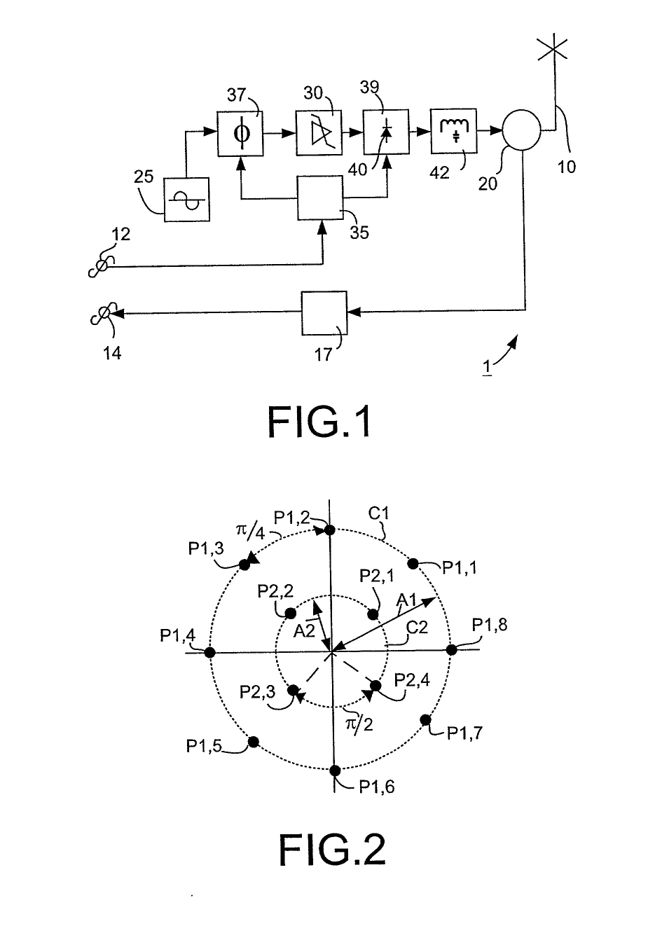

FIG. 1 shows the diagram of an apparatus according to the invention, FIG. 2 shows an example of a modulation constellation used by the apparatus according to the invention.

In FIG. 1 is represented an apparatus according to the invention. In this example it is a transceiver 1. It comprises an antenna 10 which is used both for transmitting and receiving information signals. The information signals to be transmitted are shown in the form of digital data which are applied to the terminal 12 and the received data are rendered available on terminal 14. These received data are processed by a receiving circuit 17 whose input is connected to the antenna 10 via an antenna duplexer 20. The data signals applied to the data input are transmitted via a carrier signal produced by a carrier generator 25. The carrier signals are amplified by a non-linear amplifier 30, that is to say, an amplifier operating, for example, in class C, or else in class D.

Within the framework of the described example, the data are transmitted by phase and amplitude modulating the carrier wave produced by the generator 25. For this purpose, the data to be transmitted are applied first of all to a configuration circuit 35 which gives a phase-amplitude configuration for each data or for each group of data. In this way a constellation is obtained as this is shown in FIG. 2. This configuration circuit controls a phase modulator 37 and an amplitude modulator 39.

According to the invention, the amplitude modulator 39 is placed at the output of the amplifier circuit 30, whereas the phase modulator 37 is preferably placed before the amplifier 30 to avoid working with high-amplitude signals.

The amplitude modulator 39 is advantageously realized by means of attenuating diodes which are known by the name of PIN diodes. In FIG. 1 such a PIN diode PIN 40 is shown in the modulator 39.

The invention also proposes to utilize a filter circuit 42 of the low-pass type or band-pass type to eliminate the parasitic spectrum residues which may occur at the output of the amplitude modulator 39.

It should be observed that the phase modulation advantageously happens with low-amplitude signals. The non-linear amplifier does not affect the phase modulation.

FIG. 2 shows an example of a constellation of the modulation that may be used. The various points of this constellation are situated on two circles C1 and C2 represented in dotted lines. On the circle C1 there are 8 points P1,1, P1,2, . . . P1,8 which correspond to the same amplitude A1 of the carrier and they are an angular distance π/4 apart. The points of the circle C2, which are referred to as P2,1, P2,2, . . . P2,4 correspond to an amplitude A2 which is lower than A1. Their angular distance is equal to π/2. Thus, to move the points of the circle C1 to the circle C2 and the other way around, the modulator 40 will be influenced which modulator may be formed, as has already been said, by an assembly of PIN diodes which can be adjusted depending on two attenuation values. For the various angular distances, the phase modulator 37 will be influenced.

The invention is applied to various apparatus satisfying the EDGE (GSM) standards and GSM/D-AMPS standards.

Summarizing, for modulating carrier signals, the apparatus of the invention comprises:

a phase modulation of these signals,

an amplification of the phase-modulated signals by means of a non-linear and high-efficiency amplifier,

an amplitude modulation of the amplified signals,

a supply of amplitude-modulated signals to a user circuit.

It will be obvious that the invention covers the case where it is not useful to phase modulate said carrier signals.

1. An apparatus comprising an amplitude-modulated signal transmitter preferably formed by a non-linear amplifier for supplying signals to a user circuit based on a carrier signal generator, characterized in that it comprises at least an amplitude modulator which has an amplitude modulation input for receiving information to be transmitted and which is placed between said amplifier and said user circuit.

2. An apparatus as claimed in claim 1, comprising an amplitude and phase-modulated signal transmitter, characterized in that it comprises a phase modulator which has a phase modulation input and which is placed between said carrier signal generator and said amplifier.

3. An apparatus as claimed in claim 1 or 2, characterized in that it comprises a filter circuit situated between the user circuit and said amplifier.

4. An apparatus as claimed in one of the claims 1 to 3, characterized in that the amplitude modulator comprises PIN diodes.

5. An apparatus as claimed in one of the claims 1 to 4, characterized in that it corresponds to the EDGE standards.

6. An apparatus as claimed in one of the claims 1 to 4, characterized in that it corresponds to the GSM/D-AMPS standards.

7. A method implemented in one of the apparatus as claimed in one of the claims 1 to 6, of amplitude-modulating signals, characterized in that it comprises the following successive steps:
amplification of the signals by means of a non-linear amplifier,
amplitude modulation of the amplified signals,
supply of the amplitude-modulated signals to a user circuit.

8. A method implemented in one of the apparatus as claimed in one of the claims 1 to 6, of amplitude-modulating signals, characterized in that it comprises the following successive steps:
phase modulation of the signals,
amplification of the phase-modulated signals by means of a non-linear amplifier,
amplitude modulation of the amplified signals,
supply of the amplitude-modulated signals to a user circuit.
